(19) United States
(12) Patent Application Publication
(10) Pub. No.: US 2006/0141804 A1
(43) Pub. Date: Jun. 29, 2006

(54) Method and apparatus to facilitate electrostatic discharge resiliency

(76) Inventors: Cathryn E. Goodman, Glen Ellyn, IL (US); Dean E. Banwart, Algonquin, IL (US); Miles R. Jackson, North Barrington, IL (US); Mark P. Lill, Elgin, IL (US)

Correspondence Address: MOTOROLA, INC., 1303 EAST ALGONQUIN ROAD, IL01/3RD, SCHAUMBURG, IL, 60196, US

(21) Appl. No.: 11/025,468

(22) Filed: Dec. 28, 2004

(51) Int. Cl. H01L 21/31; H01L 21/469

(52) U.S. Cl. 438/758

(57) ABSTRACT

A circuit element (such as an asperity sensor circuit (11)) as is formed (21) using semiconductor fabrication processing has a high resistance layer formed (22) thereover. The high resistance layer is preferably formed using semiconductor fabrication processing. The high resistance layer can be comprised of a variety of materials and can assume a wide variety of configurations.

### FIELD OF THE INVENTION

This invention relates generally to semiconductor fabrication techniques and results and more particularly to electrostatic discharge protection.

### BACKGROUND OF THE INVENTION

Circuit elements formed using semiconductor fabrication processing comprise a well-understood area of endeavor. Such processing techniques comprise, for example, such activities as material deposition, photolithography/masking, etching, and so forth. It is also known that some circuit elements fabricated using such materials are exposed, during normal usage, to potentially debilitating electrostatic discharge. Such a discharge can render many circuit elements temporarily or, more often than not, permanently disabled.

For example, many asperity detectors as are used to detect, for example, fingerprints, glove “prints,” and so forth are particularly susceptible to this phenomenon. In particular, such detectors often operate through intimate contact between a surface (such as a fingertip) having asperities to be detected and a detection pad. This juxtapositioning, however, also readily permits a static charge as borne by the holder of the surface having asperities to be detected to be passed via the detection pad to the circuit element that comprises the asperity sensor (and particularly so when the asperity sensor comprises a resistive-discharge based asperity detector).

One prior art solution proposes the use of anisotropic conductive coating materials to aid in protecting such a circuit element from electrostatic discharge. While effective, the formulation and application of such a coating can require strict process controls. This approach also typically introduces additional (and new) sets of variables to the semiconductor fabrication process which also then potentially further challenges meeting quality control goals in this setting.

### BRIEF DESCRIPTION OF THE DRAWINGS

The above needs are at least partially met through provision of the method and apparatus to facilitate electrostatic discharge resiliency described in the following detailed description, particularly when studied in conjunction with the drawings, wherein:

FIG. 1 comprises a prior art schematic depiction of a resistive-discharge asperity detector;

FIG. 2 comprises a flow diagram as configured in accordance with various embodiments of the invention;

FIG. 3 comprises a schematic depiction of a resistive-discharge asperity detector as configured in accordance with various embodiments of the invention;

FIG. 4 comprises a schematic depiction of a resistive-discharge asperity detector as configured in accordance with various embodiments of the invention;

FIG. 5 comprises a schematic depiction of a resistive-discharge asperity detector as configured in accordance with various embodiments of the invention;

FIG. 6 comprises a schematic depiction of a resistive-discharge asperity detector as configured in accordance with various embodiments of the invention;

FIG. 7 comprises a schematic depiction of a resistive-discharge asperity detector as configured in accordance with various embodiments of the invention;

FIG. 8 comprises a schematic depiction of a resistive-discharge asperity detector as configured in accordance with various embodiments of the invention;

FIG. 9 comprises a schematic depiction of a resistive-discharge asperity detector as configured in accordance with various embodiments of the invention;

FIG. 10 comprises a schematic depiction of a resistive-discharge asperity detector as configured in accordance with various embodiments of the invention;

FIG. 11 comprises a schematic depiction of a resistive-discharge asperity detector as configured in accordance with various embodiments of the invention; and

FIG. 12 comprises a schematic depiction of a resistive-discharge asperity detector as configured in accordance with various embodiments of the invention.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION OF THE INVENTION

Generally speaking, pursuant to these various embodiments, a circuit element formed using semiconductor fabrication processing has a high resistance layer formed thereover also using semiconductor fabrication processing. So configured, the circuit element is thereby protected from externally sourced electrostatic discharge as the discharge is largely borne by the high resistance layer.

This layer can assume various forms including substantially planar forms, substantially pyramidal forms, substantially diamond-shaped forms, substantially spheroid forms, substantially ellipsoid-shaped forms, and so forth. Depending upon the specific approach taken, this layer can comprise a single layer or can comprise a plurality of layers. Also depending upon the specific approach taken, this layer can comprise a single entity or can be comprised of a plurality of discrete elements (for example, this layer can comprise a plurality of sphere-shaped elements).

This high resistance layer is readily formed using the same kinds of semiconductor fabrication techniques as are used to form the circuit element to be protected. This means, of course, that application of these teachings in a commercial setting avoids introducing a new set of variables. As a result, quality control can be achieved through observance and application of already-existing behaviors and techniques.

These and other benefits may become clearer upon making a thorough review and study of the following detailed description. Referring now to the drawings, and in particular to FIG. 1, for purposes of providing an illustrative, albeit non-exhaustive context within which to convey these teachings, a prior art resistive-discharge based asperity detector 10 can comprise a circuit element comprising asperity sensor circuitry 11 that couples to an exposed conductive pad 12 via an electrically conductive pathway 13. (Typically, an asperity detector will include hundreds or even thousands of such sensors and pads; only one of each is shown in this illustration for the sake of clarity). This exposed conductive pad 12 is comprised, for example, of TiN. These various elements are formed using semiconductor fabrication processing in accordance with well-understood prior art technique. (Additional information regarding such a resistive-discharge based asperity detector can be found in pending U.S. Patent Application No. 2003/0108226, entitled METHOD AND APPARATUS FOR ASPERITY SENSING AND STORAGE and incorporated herein by this reference.)

With reference to FIG. 2, these teachings contemplate a process 20 wherein a circuit element is provided 21 using semiconductor fabrication processing (such as, but certainly not limited to, an active circuit such as the asperity sensor circuitry 11 described above and/or a conductive pad 12 which couples to such an active circuit) and wherein a high resistance layer is then formed 22 over that circuit element using, again, semiconductor fabrication processing (such as, for example, complimentary metal oxide semiconductor processing). So configured, the high resistance layer serves to protect the circuit element from externally sourced electrostatic discharge. This high resistance layer may have, for example, a characteristic resistance of about 10K ohms and can be comprised of any of a wide variety of suitable materials, including but not limited to metals (such as but not limited to nickel alloys, germanium, and the like), polysilicon, and so forth.

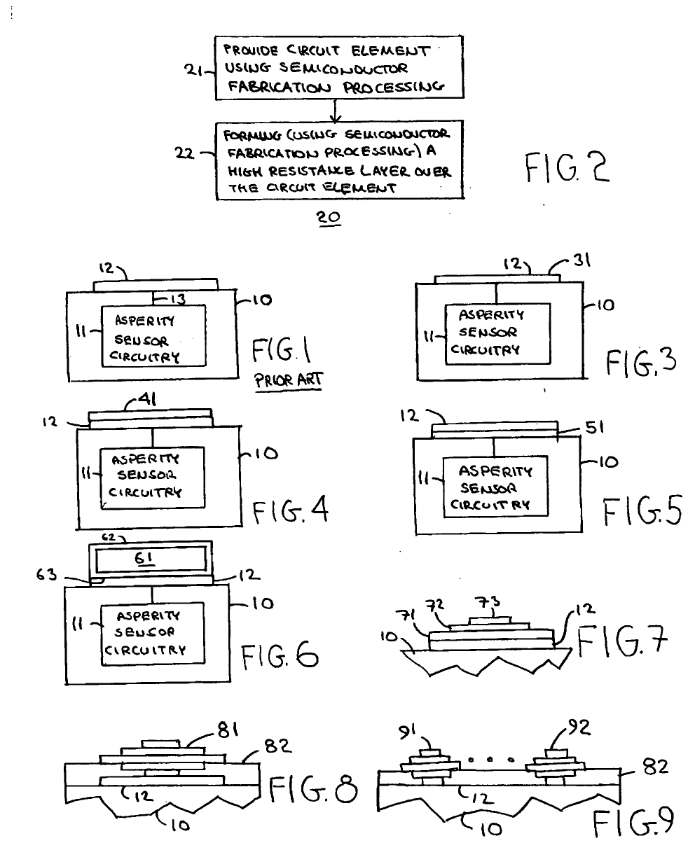

This formation 22 of a high resistance layer can be realized in a wide variety of ways. With reference to FIG. 3, the exposed conductive pad 12 itself can comprise a high resistance metal 31 such as nickel. So configured, the high resistance metal 31 serves both to suitably dissipate electrostatic discharge while also providing a suitable and effective contact surface to effect the purposes of the resistive-discharge based asperity detector. With reference to FIG. 4, it would also be possible to form a layer 41 of high resistance material (such as Ni₂O₃, Ni, or Ni₂O₃, to name a few) over the conductive pad 12 or, and referring now to FIG. 5, to form such a layer 51 between the conductive pad 12 and the circuit element 11. In each such case the high resistance material will again serve to dissipate an electrostatic discharge while also permitting a desired flow of current in support of the operation of the asperity sensor circuitry 11.

There are other ways by which this high resistance layer can be formed as well. With reference to FIG. 6, the resistive layer can comprise a layer of nickel 61 bounded on its exterior surfaces (and in particular a first surface 62 and a second surface 63 on a side opposite the first surface 62) by a layer of oxidized nickel.

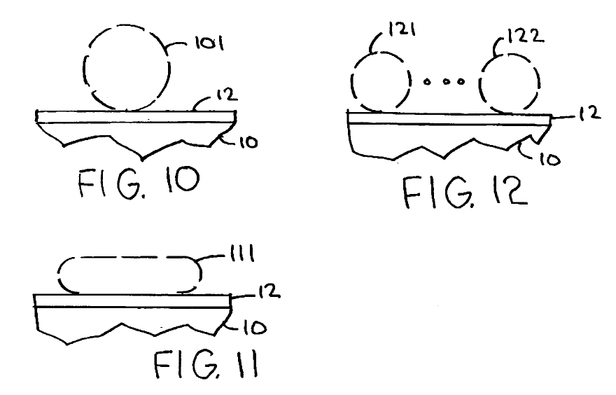

These teachings also contemplate a variety of configurations for such a high resistance layer. In the examples shown above, the high resistance layer essentially comprises a substantially planar shaped layer. Other shapes are possible. As one example, and referring now to FIG. 7, the high resistance layer can be comprised of a plurality of individual layers 71, 72, and 73 wherein each succeeding layer is smaller than the preceding layer to thereby achieve a pyramidal or conically shaped result (depending upon whether these layers are rectangular or circular in shape). Depending upon the materials used, the number of layers, and so forth, such a layered and stepped configuration may be particularly helpful in dissipating electrostatic discharges. Such layers are readily formed using standard semiconductor fabrication processing as will be well appreciated by those skilled in the art. (In the embodiment shown, only three layers are provided. Those skilled in the art will now recognize that any number of layers can be employed as desired. The skilled artisan will also understand and appreciate that the relative size of each succeeding layer can also be selected to provide a smoother, or more stepped, transition from layer to layer.)

With reference to FIG. 8, yet another approach would employ the aforementioned layered technique to configure the high resistance layer as a diamond-shaped layer 81. To facilitate formation of such an embodiment, it may be helpful to also form a layer 82 of nonconductive material in order to assure adequate support for the high resistance layer 81. Such a configuration may again prove particularly useful with respect to dissipating a significant electrostatic discharge.

In the embodiments described above, the high resistance layer comprises a single integral element. It would also be possible, however, to configure the high resistance layer as a plurality of discrete elements. To illustrate, and referring now to FIG. 9, a plurality of multi-layer diamond-shaped elements 91 and 92 (as described above) can be separately formed to serve, in the aggregate, as a high resistance layer. It would also be possible, of course, to form such a layer using a plurality of differently shaped elements (such as a mixture of pyramid-shaped elements and diamond-shaped elements, for example).

Other shapes are possible as well, of course. For example, as is schematically represented in FIG. 10 and presuming the use of a number of layers, it would be possible to provide one or more spherically-shaped elements 101, alone or as a plurality (with such a plurality being schematically suggested in FIG. 12 by reference numerals 121 and 122). Referring to FIG. 11, the high resistance layer could also be configured as an elliptically-shaped element 111 if so desired. Those skilled in the art will recognize and understand that these examples are illustrative only and are not to be viewed as an exhaustive listing of all possibilities in this regard.

So configured, standard silicon processing techniques, such as complimentary metal oxide semiconductor processing, are readily employed to form a repeatable and reliable high resistive layer that serves to protect one or more circuit elements from electrostatic discharge. In a preferred approach this high resistance layer also serves as a conductive pathway that couples to an input of the protected circuit element such that a desired signal of interest can and will be provided to the input of the protected circuit element. This high resistance layer can be comprised of metal or other suitable material. For example, polysilicon can be used as the resistive material (polysilicon being deployable in various ways, including by doping already present silicon or by sputtering amorphous polysilicon on an existing surface).

Those skilled in the art will recognize that a wide variety of modifications, alterations, and combinations can be made with respect to the above described embodiments without departing from the spirit and scope of the invention, and that such modifications, alterations, and combinations are to be viewed as being within the ambit of the inventive concept.

We claim:

1. A method to improve electrostatic discharge resiliency for a circuit element, comprising:
providing a circuit element using semiconductor fabrication processing;
forming, using semiconductor fabrication processing, a high resistance layer over the circuit element to thereby protect the circuit element from externally sourced electrostatic discharge.

2. The method of claim 1 wherein forming, using semiconductor fabrication processing, a high resistance layer further comprises forming, using complimentary metal oxide semiconductor processing, the high resistance layer.

3. The method of claim 1 wherein forming, using semiconductor fabrication processing, a high resistance layer further comprises forming, using semiconductor fabrication processing, a high resistance layer comprised of metal.

4. The method of claim 3 wherein forming, using semiconductor fabrication processing, a high resistance layer comprised of metal further comprises forming, using semiconductor fabrication processing, a high resistance layer formed of at least one of nickel alloy and germanium.

5. The method of claim 1 wherein forming, using semiconductor fabrication processing, a high resistance layer further comprises forming, using semiconductor fabrication processing, a high resistance layer comprised of polysilicon.

6. The method of claim 1 wherein providing a circuit element using semiconductor fabrication processing further comprises providing a circuit element comprising:
an active circuit;
a conductive pad operably coupled to the active circuit.

7. The method of claim 6 wherein forming, using semiconductor fabrication processing, a high resistance layer further comprises forming the high resistance layer on the conductive pad.

8. The method of claim 7 wherein the conductive pad is comprised of TiN.

9. The method of claim 6 wherein forming, using semiconductor fabrication processing, a high resistance layer further comprises forming the high resistance layer between the active circuit and the conductive pad,

10. The method of claim 1 wherein forming, using semiconductor fabrication, processing, a high resistance layer further comprises forming a high resistance layer having a substantially planar shape.

11. The method of claim 1 wherein forming, using semiconductor fabrication processing, a high resistance layer further comprises forming a high resistance layer having a substantially pyramidal shape.

12. The method of claim 1 wherein forming, using semiconductor fabrication processing, a high resistance layer further comprises forming, using semiconductor fabrication processing, a high resistance layer having a substantially diamond-shaped shape.

13. The method of claim 1 wherein forming, using semiconductor fabrication processing, a high resistance layer further comprises forming, using semiconductor fabrication processing, a high resistance layer comprised of a high resistance metal having an oxide surface disposed thereabout.

14. A semiconductor apparatus comprising:
a circuit element formed using semiconductor fabrication processing;
a high resistance layer that is formed using semiconductor fabrication processing and that is disposed between the circuit element and an exterior to thereby protect the circuit element from externally sourced electrostatic discharge.

15. The semiconductor apparatus of claim 14 wherein the semiconductor apparatus comprises an asperity detector.

16. The semiconductor apparatus of claim 15 wherein the circuit element comprises an asperity sensor.

17. The semiconductor apparatus of claim 14 wherein the high resistance layer has a shape that substantially comports with at least one of:
a planar shape;
a pyramid shape;
a diamond shape;
a spherical shape;
an elliptical shape.

18. The semiconductor apparatus of claim 14 and further comprising a plurality of discrete, separated high resistance layers that are formed using semiconductor fabrication processing and that are disposed between the circuit element and the exterior.

19. The semiconductor apparatus of claim 14 wherein the high resistance layer is comprised of at least one of:
a high resistance metal;
a polysilicon material.
